(19) United States
(12) Patent Application Publication
(10) Pub. No.: US 2025/0239438 A1
(43) Pub. Date: Jul. 24, 2025

(54) MULTI-LAYER FOCUS RING FOR PLASMA SEMICONDUCTOR PROCESSING

(71) Applicant: BEIJING NAURA MICROELECTRONICS EQUIPMENT CO., LTD., Beijing (CN)

(72) Inventors: Yulin PENG, Beijing (CN); Jinrong ZHAO, Beijing (CN)

(21) Appl. No.: 18/702,241

(22) PCT Filed: Aug. 25, 2022
(86) PCT No.: PCT/CN2022/114863

§ 371 Date: Apr. 17, 2024

(51) Int. Cl. H01J 37/32; H01L 21/66

(52) U.S. Cl. CPC H01J 37/32642; H01L 22/12

(57) ABSTRACT

The present disclosure relates to plasma semiconductor processes and related components and tools. In one embodiment, a focus ring includes first and second ring layers. An upper surface of the second ring layer is configured to support the first ring layer by a lower surface of the first ring layer contacting the upper surface. The lower and upper surfaces are periodic circumferentially and have a same period length. At least one of the lower and upper surfaces includes a first protrusion radial line (PRL), a second PRL, and a recess radial line (RRL) disposed between the first and second PRLs. The period length is from the first PRL to the second PRL. The lower and/or upper surface from the first PRL to the RRL is continuous and from the RRL to the second PRL is continuous. The second ring layer is rotatably movable relative to the first ring layer.

### BACKGROUND

Plasma processing has become ubiquitous in the semiconductor industry. Plasma semiconductor processes have been used to etch materials, deposit materials, and the like. Such plasma processes have been found to have improved processing qualities or resulting characteristics on the semiconductor substrate. For example, plasma enhanced chemical vapor deposition (PECVD) has been found to have advantages over previous chemical vapor deposition (CVD) processes, including lower deposition temperature, increased material purity, and improved step coverage. However, the introduction of plasma has resulted in various challenges.

### SUMMARY

One aspect of the present disclosure provides a component for semiconductor processing. The component includes a focus ring configured to laterally encircle a semiconductor substrate during plasma semiconductor process. The focus ring includes a first ring layer having a lower surface and includes a second ring layer having an upper surface. The upper surface is configured to support the first ring layer by the lower surface contacting the upper surface. The lower surface and the upper surface are periodic circumferentially. The lower surface and the upper surface have the same period length at a same first radial distance from a center of the focus ring. At least one of the lower surface and the upper surface includes a first protrusion radial line, a first recess radial line, and a second protrusion radial line. The first recess radial line is disposed laterally between the first protrusion radial line and the second protrusion radial line. The period length at the first radial distance is from the first protrusion radial line to the second protrusion radial line. The at least one of the lower surface and the upper surface from the first protrusion radial line to the first recess radial line is continuous. At least one of the lower surface and the upper surface from the first recess radial line to the second protrusion radial line is continuous. The second ring layer is laterally, rotatably movable relative to the first ring layer while the upper surface supports the first ring layer.

Another aspect of the present disclosure provides processing equipment for semiconductor processing. The processing equipment includes a chamber, a substrate support, and a focus ring rotation assembly. The chamber has an internal volume within the chamber. The substrate support is disposed in the internal volume of the chamber. The substrate support has a support surface configured to support a semiconductor substrate. The substrate support includes a flange configured to support a focus ring laterally encircling the support surface. The focus ring rotation assembly is disposed at least partially in the internal volume of the chamber. The focus ring rotation assembly is configured to rotate at least a portion of the focus ring laterally around an axis normal to the support surface. The focus ring rotation assembly includes a frame that is configured to rotate laterally around the axis normal to the support surface.

Another aspect of the present disclosure provides a method for semiconductor processing. The method includes adjusting the height of a focus ring. The focus ring is disposed laterally encircling a semiconductor substrate in a chamber of processing equipment. The focus ring includes a first ring layer and a second ring layer. Adjusting the height of the focus ring includes rotating the second ring layer relative to the first ring layer. The first ring layer has a lower surface. The second ring layer has an upper surface. The lower surface is disposed on and contacting the upper surface. The lower surface and the upper surface are periodic circumferentially. The lower surface and the upper surface have the same period length at a same first radial distance from a center of the focus ring. At least one of the lower surface and the upper surface includes a first protrusion radial line, a first recess radial line, and a second protrusion radial line. The first recess radial line is disposed laterally between the first protrusion radial line and the second protrusion radial line. The period length at the first radial distance is from the first protrusion radial line to the second protrusion radial line. The at least one of the lower surface and the upper surface from the first protrusion radial line to the first recess radial line is continuous. At least one of the lower surface and the upper surface from the first recess radial line to the second protrusion radial line is continuous. The method includes generating plasma in a processing volume of the chamber while the focus ring is disposed laterally encircling the semiconductor substrate. The semiconductor substrate is exposed to plasma.

Another aspect of the present disclosure provides a method for semiconductor processing. The method includes performing plasma semiconductor process having first process conditions on a first plurality of substrates using processing equipment. The processing equipment includes a substrate support configured to support a substrate during the plasma semiconductor process. A focus ring is disposed laterally encircling the substrate during the plasma semiconductor process. The focus ring has a first ring layer and a second ring layer supporting and contacting the first ring layer. The height of the focus ring is adjustable by rotating the second ring layer relative to the first ring layer. The first process conditions correspond to a first amount of rotation of the second ring layer relative to the first ring layer to implement a first height of the focus ring during the plasma semiconductor process. The method includes measuring respective first characteristics of the first plurality of substrates proximate to respective centers of the first plurality of substrates. The first characteristics are formed by the plasma semiconductor process. The method includes measuring respective second characteristics of the first plurality of substrates proximate to respective edges of the first plurality of substrates. The second characteristic is formed by the plasma semiconductor process. The method includes, by a processor-based system, determining second process conditions to be applied while performing the plasma semiconductor process on a second plurality of substrates based on the first characteristics and the second characteristics. The second process conditions correspond to a second amount of rotation of the second ring layer relative to the first ring layer to implement a second height of the focus ring during the plasma semiconductor process. The method includes performing the plasma semiconductor process having the second process conditions on the second plurality of substrates using the processing equipment.

The foregoing summary outlines various features of embodiments of the present disclosure so that the following detailed description may be better understood. Additional features and advantages of such embodiments will be described hereinafter. The described embodiments may be readily utilized as a basis for modifying or designing other embodiments that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a schematic view of processing equipment for semiconductor processing according to some embodiments.

FIG. 2A is a layout view of a focus ring according to some embodiments.

FIG. 2B is a cross-sectional view of the focus ring of FIG. 2A according to some embodiments.

FIG. 2C is a cross-sectional view of the focus ring of FIG. 2A according to some embodiments.

FIG. 2D is a layout view of the cross-sectional portion of the focus ring of FIG. 2C according to some embodiments.

FIGS. 3 and 4 illustrate height adjustment of the focus ring of FIGS. 2A-2D according to some embodiments.

FIG. 5 is a simplified cross-sectional view of a focus ring rotation assembly according to some embodiments.

FIG. 6 is a perspective view of the focus ring rotation assembly of FIG. 5 according to some embodiments.

FIGS. 7A, 7B, and 7C are a layout view, a first cross-sectional view, and a second cross-sectional view, respectively, of the focus ring on a flange of a substrate support according to some embodiments.

FIGS. 8A and 8B are a layout view and a cross-sectional view, respectively, of the focus ring on a flange of a substrate support according to some embodiments.

FIGS. 9 and 10 illustrate conceptually how height of a focus ring can contribute to plasma control according to some embodiments.

FIG. 11 is a processor-based system according to some embodiments.

FIG. 12 is a flow chart of a method of semiconductor processing according to some embodiments.

FIG. 13 is a flow chart of a method for semiconductor processing according to some embodiments.

FIGS. 14, 15, 16, 17, and 18 are cross-sectional views of respective focus rings according to some embodiments.

The drawings, and accompanying detailed description, are provided for understanding of features of various embodiments and do not limit the scope of the appended claims. The embodiments illustrated in the drawings and described in the accompanying detailed description may be readily utilized as a basis for modifying or designing other embodiments that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An embodiment may not have all the aspects or advantages shown. An aspect or an advantage described in conjunction with a particular embodiment is not necessarily limited to that embodiment and can be practiced in any other embodiments even if not so illustrated or if not so explicitly described. Further, methods described herein may be described in a particular order of operations, but other methods according to other embodiments may be implemented in various other orders (e.g., including different serial or parallel performance of various operations) with more or fewer operations.

The present disclosure relates to plasma semiconductor processes and to components and processing equipment for plasma semiconductor processes. Some embodiments described herein include a focus ring that comprises multiple layers. Generally, the first ring layer (e.g., a top layer) of the focus ring has a lower surface, and a second ring layer (e.g., a bottom layer) has an upper surface. The upper surface is configured to contact and support the lower surface of the first ring layer. The upper and lower surfaces are configured such that rotation of the second ring layer relative to the first ring layer adjusts the height of the focus ring. In some embodiments, continuous rotation of the second ring layer relative to the first ring layer results in oscillation of the height of the focus ring without having to have a hard reset of the first or second ring layers for height adjustment.

Some embodiments described herein include processing equipment in which such a focus ring may be used. The processing equipment includes a focus ring rotation assembly that is configured to rotate the second ring layer. The processing equipment can also include a substrate support that includes mechanisms to prevent significant rotation of the first ring layer when the second ring layer rotates. Such mechanisms may include stop pins that extend from the substrate support that engage the first ring layer to prevent significant rotation of the first ring layer.

Other embodiments described herein include a method of semiconductor processing using such focus ring and processing equipment, for example. Further embodiments include a method for semiconductor processing for determining a height of a focus ring to be implemented in subsequent processing of semiconductor substrates based on results of previous processing of semiconductor processing.

Additionally, in some embodiments, a focus ring may include an electrode on which a voltage, such as a radio frequency (RF) signal, may be applied. Processing equipment may include components to apply such a voltage on the electrode of the focus ring. Plasma semiconductor process may include applying such a voltage on the electrode.

Plasma non-uniformity in a semiconductor process can result in defective integrated circuit (IC) dies being manufactured. Plasma non-uniformity has been observed between the center of a semiconductor substrate (e.g., a wafer) and proximate an edge of the semiconductor substrate. Since a significant number of IC dies are manufactured proximate an edge of a semiconductor substrate, plasma non-uniformity at the edge of the semiconductor substrate can result in a significant loss of yield.

Structural differences at the edge of a semiconductor substrate compared to the center of the semiconductor substrate can contribute to plasma non-uniformity between a center and an edge of the semiconductor substrate. For example, at the edge of the semiconductor substrate, the structure that contains or defines plasma may be different than at the center of the semiconductor substrate. At the center, the plasma is contained or defined by a flat, lateral surface of the semiconductor surface, whereas the edge with its vertical side is structurally different from the flat, lateral surface. A focus ring encircling the semiconductor substrate may be used to mitigate such a structural difference; however, a gap may exist between the focus ring and the semiconductor substrate due to manufacturing tolerances. The plasma sheath of the plasma may bend around the edge into the gap, which can lead to ion bombardment of the semiconductor substrate near the edge that is at an angle different than at the center of the semiconductor substrate.

Further, the physical structure of the processing equipment can further determine, at least in part, the electromagnetic field used to generate plasma. The structure of the electrodes between which the plasma is generated can determine the electromagnetic field. At the center of an electrode, the electromagnetic field may be modeled as generated from an infinite plane, with no or little edge effects. Near an edge of the electrode, edge effects become more pronounced, which can reduce and/or change the directionality of the electromagnetic field. As a result, the plasma density can be different at an edge of the semiconductor substrate compared to the center of the substrate. Further, the edge of the electrode is nearer to a wall of the chamber of the processing equipment, which can create a low resistivity electromagnetic loop that can result in plasma density and ion energy difference between the center and edge.

Some embodiments can address and/or mitigate some of these challenges related to plasma semiconductor process. By adjusting the height of the focus ring, the plasma sheath may be adjusted to cause more uniform angles of ion bombardment at the edge relative to the center of the semiconductor substrate. Additionally, by applying a voltage to an electrode of the focus ring, the electromagnetic field can be controlled to cause more uniform angles of ion bombardment at the edge relative to the center. Other advantages or benefits can be achieved using various aspects described herein.

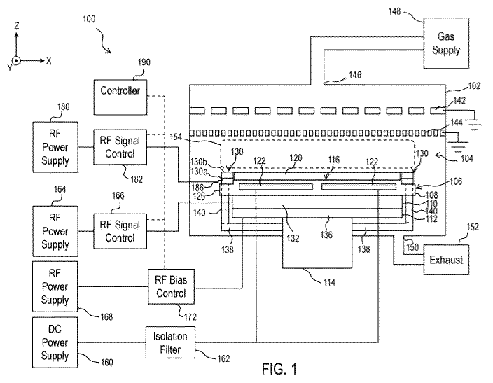

FIG. 1 is a schematic view of processing equipment 100 for semiconductor processing according to some embodiments. FIG. 1 includes an X-Y-Z axis for ease of describing various orientations, and such axis is reproduced according to orientation in other figures. The processing equipment 100 in FIG. 1 is illustrated simplistically so as to not obscure various aspects described herein. A person having ordinary skill in the art will readily understand other aspects of the processing equipment 100. The processing equipment 100 is shown as a capacitively coupled plasma (CCP) processing equipment in this embodiment. In other embodiments, the processing equipment 100 can be configured as an inductively coupled plasma (ICP) processing equipment, electron cyclotron resonance (ECR) processing equipment, or another processing equipment. A person having ordinary skill in the art will readily understand aspects described herein as being applicable to such other processing equipment. The processing equipment 100 can be for performing plasma semiconductor process, such as sputtering, physical vapor deposition (PVD), modified double plasma (MDP), plasma-enhanced chemical vapor deposition (PECVD), ion beam etching (IBE), reactive ion etching (RIE), and other semiconductor processes.

The processing equipment 100 includes chamber 102. Chamber 102 has an internal volume 104 that is defined by the inner walls of the chamber 102. The processing equipment 100 includes a substrate support 106 disposed in the internal volume 104 of the chamber 102. Substrate support 106 includes an electrostatic chuck (ESC) 108, a mid-plate 110, and a baseplate 112. In the illustrated configuration, the mid-plate 110 is disposed over and on the baseplate 112, and the ESC 108 is disposed over and on the mid-plate 110. The substrate support 106 is disposed on and is supported by a pedestal 114. The baseplate 112 is disposed over and on the pedestal 114.

The substrate support 106 has a support surface 116 that is configured to support a semiconductor substrate 120 during a semiconductor process. During a semiconductor process, a semiconductor substrate 120 is disposed on the support surface 116 of the substrate support 106. The support surface 116 is a top surface of the ESC 108 in the illustrated embodiment. The support surface 116, in the illustration of FIG. 1, is in an x-y plane.

The ESC 108 includes chucking electrodes 122. The chucking electrodes 122 are configured to have a direct current (DC) voltage applied thereto for chucking the semiconductor substrate 120 on the support surface 116. The ESC 108 can include a dielectric material that coats the chucking electrodes 122 to provide electrical isolation from direct contact between the chucking electrodes 122. The ESC 108 further has a flange 126 at a lateral periphery of the ESC 108. Flange 126 is configured to support a focus ring 130 that laterally encircles the semiconductor substrate 120 during plasma semiconductor process. Flange 126 can be formed of the dielectric material that coats the chucking electrodes 122. The dielectric material can be or include any non-conductive material, such as aluminum oxide (Al2O3), yttrium oxide (Y2O3), silicon oxide (SiO2), the like, or a combination thereof. In some embodiments, the ESC 108 may include resistive heating elements configured to have an electrical current flow therethrough, which can generate thermal energy that is conducted to the semiconductor substrate 120.

As detailed subsequently, the focus ring 130 includes a bottom layer 130a and a top layer 130b over the bottom layer 130a. The bottom layer 130a is supported by the flange 126 of the ESC 108, and the top layer 130b is supported by the bottom layer 130a. The bottom layer 130a is rotatable around a vertical axis (e.g., a z-direction axis). While rotating, the bottom layer 130a slides or travels along the surface of flange 126 that supports the focus ring 130. The top layer 130b generally is not significantly rotatable. As the bottom layer 130a rotates, configurations of an upper surface of the bottom layer 130a and a lower surface of the top layer 130b cause the top layer 130b to be translated in a vertical direction (e.g., a z-direction). The translation of the top layer 130b causes a height of the focus ring 130 relative to the semiconductor substrate 120 to be varied.

The mid-plate 110 includes an RF electrode 132. The RF electrode 132 may have a dielectric material thereon to provide electrical isolation from direct contact of the RF electrode 132 to other components. In some embodiments, the mid-plate 110 includes fluid channels that are configured to have a fluid (e.g., a liquid) flowing therethrough to remove and dissipate thermal energy from the semiconductor substrate 120. The fluid channels may be referred to as a cooler.

Baseplate 112 includes a bias electrode 136. The bias electrode 136 is configured to have a bias signal (e.g., an RF signal) applied thereto to promote drivability of the RF electrode 132. The bias electrode 136 may have a dielectric material thereon to provide electrical isolation from direct contact of the bias electrode 136 to other components.

The processing equipment 100 includes a focus ring rotation assembly. The focus ring rotation assembly includes a rotatable frame 138 and rotation pins 140 vertically projecting from the rotatable frame 138. The rotatable frame 138 laterally projects from the pedestal 114. The rotation pins 140 are supported by and extend vertically from the rotatable frame 138. The rotation pins 140 extend through slots through the flange 126 of the ESC 108 and mechanically couple to the focus ring 130 (e.g., the bottom layer 130a). The rotatable frame 138 is rotatable around a vertical axis (e.g., a z-direction axis), and rotation of the rotatable frame 138 causes the bottom layer 130a to rotate around the vertical axis. Additional details of the focus ring rotation assembly are described subsequently.

The processing equipment 100 further includes a gas distribution plate 142 and a gas showerhead 144 disposed in the internal volume 104 of chamber 102. The gas distribution plate 142 has openings therethrough, and the gas showerhead 144 has openings therethrough. The gas distribution plate 142 and the gas showerhead 144 are electrically coupled to a ground node (e.g., are electrically grounded). Chamber 102 has a gas inlet 146 fluidly coupled to a gas supply system 148, and has a gas outlet 150 fluidly coupled to an exhaust system 152. The gas distribution plate 142 and gas showerhead 144 are positioned in the internal volume 104 of the chamber 102 relative to the substrate support 106 such that, during a semiconductor process, a gas flows from the gas supply system 148, through the gas inlet 146, through the openings through the gas distribution plate 142, and then through the openings through the gas showerhead 144 to a processing volume 154 in the internal volume 104. The processing volume 154 is disposed between the gas showerhead 144 and the substrate support 106 and is generally where plasma is generated (using the gas flowed into the processing volume 154) during a semiconductor process. A semiconductor substrate 120 disposed on the support surface 116 of the substrate support 106 is exposed to plasma in the processing volume 154 during the semiconductor process. The gas can then flow through the gas outlet 150 to the exhaust system 152 to be exhausted out of the internal volume 104 of the chamber 102.

The processing equipment 100 includes a DC power supply 160 and isolation filter 162. DC power supply 160 is configured to generate and output a DC voltage. Output nodes (e.g., a positive output node and a negative output node) of the DC power supply 160 are electrically coupled to input nodes of the isolation filter 162, and output nodes of the isolation filter 162 are electrically coupled to respective chucking electrodes 122. The isolation filter 162 may be, for example, a low pass filter. The DC power supply 160 can be selectively turned on and off to chuck and release a semiconductor substrate 120.

The processing equipment 100 includes an RF power supply 164 and an RF signal control circuit 166. The RF power supply 164 may include an RF power generator and an RF matching network, and is configured to generate and output an RF signal, which may be a continuous RF signal and/or a pulsed RF signal, on an output node of the RF power supply 164. The output node of the RF power supply 164 is electrically coupled to an input node of the RF signal control circuit 166. The RF signal control circuit 166 is controllable to generate an adjusted RF signal based on the RF signal received from the RF power supply 164. The adjusted RF signal generated by the RF signal control circuit 166 may have an adjusted amplitude (e.g., by a gain of the RF signal control circuit 166, which may have a magnitude greater than, equal to, or less than 1) of the received RF signal and/or may have a phase offset from the received RF signal. The gain and/or phase offset may be selectable from a set of gains and/or phase offsets, respectively, that the RF signal control circuit 166 is configured to implement. The RF signal control circuit 166 has an output node that is electrically coupled to the RF electrode 132 of the mid-plate 110. The RF signal control circuit 166 is configured to output the adjusted RF signal on the output node, and hence, the adjusted RF signal can be applied to the RF electrode 132. The RF signal output by the RF signal control circuit 166 can be used for generating and/or controlling plasma in the processing volume 154.

The processing equipment 100 includes an RF power supply 168 and an RF bias control circuit 172. The RF power supply 168 may include an RF power generator and an RF matching network, and is configured to generate and output an RF signal, which may be a continuous RF signal and/or a pulsed RF signal, on an output node of the RF power supply 168. The output node of the RF power supply 168 is electrically coupled to an input node of the RF bias control circuit 172. Like the RF signal control circuit 166, the RF bias control circuit 172 is controllable to generate an adjusted RF signal based on the RF signal received from the RF bias control circuit 172. The adjusted RF signal generated by the RF bias control circuit 172 may have an adjusted amplitude (e.g., by a gain of the RF bias control circuit 172, which may have a magnitude greater than, equal to, or less than 1) of the received RF signal and/or may have a phase offset from the received RF signal. The gain and/or phase offset may be selectable from a set of gains and/or phase offsets, respectively, that the RF bias control circuit 172 is configured to implement. The RF bias control circuit 172 has an output node that is electrically coupled to the bias electrode 136 of the baseplate 112.

The baseplate 112, in this embodiment, may be strongly capacitively coupled to the RF electrode 132 in the mid-plate 110. Hence, according to some embodiments, the baseplate 112 is biased by the RF signal output by the RF bias control circuit 172 to increase drivability of the RF electrode 132 to generate plasma. The RF bias control circuit 172, in operation, outputs an RF signal that has a target amplitude and a target phase offset relative to the RF signal applied to the RF electrode 132. Having such an RF signal applied to the bias electrode 136 of the baseplate 112 permits increased drivability of the RF electrode 132 to generate and control plasma.

The processing equipment 100 includes an RF power supply 180 and an RF signal control circuit 182. The RF power supply 180 may include an RF power generator and an RF matching network, and is configured to generate and output an RF signal, which may be a continuous RF signal and/or a pulsed RF signal, on an output node of the RF power supply 180. The output node of the RF power supply 180 is electrically coupled to an input node of the RF signal control circuit 182. The RF signal control circuit 182 is controllable to generate an adjusted RF signal based on the RF signal received from the RF power supply 180. The adjusted RF signal generated by the RF signal control circuit 182 may have an adjusted amplitude (e.g., by a gain of the RF signal control circuit 182, which may have a magnitude greater than, equal to, or less than 1) of the received RF signal and/or may have a phase offset from the received RF signal. The gain and/or phase offset may be selectable from a set of gains and/or phase offsets, respectively, that the RF signal control circuit 182 is configured to implement. The RF signal control circuit 182 has an output node that is electrically coupled to an external electrical connector 186 of the bottom layer 130a of the focus ring 130. The RF signal control circuit 182 is configured to output the adjusted RF signal on the output node, and hence, the adjusted RF signal can be applied to the bottom layer 130a. The RF signal output by the RF signal control circuit 182 can be used for controlling plasma in the processing volume 154 proximate an edge of the semiconductor substrate 120.

processing equipment 100 includes a controller 190. Controller 190 can be or include any processor-based system, which may be or include a hardened processor architecture, a soft processor (e.g., implemented on programmable fabric of a field programmable gate array (FPGA)), or a combination thereof. For example, the controller 190 can be or include a computer, a server, a programmable logic controller (PLC), the like, or a combination thereof. Controller 190 can control the operation of the processing equipment 100 and can be programmed to implement operations of the processing equipment 100 as described herein. Among other things, the controller 190 is communicatively coupled to the RF signal control circuit 166, the RF bias control circuit 172, and the RF signal control circuit 182. Controller 190 can be programmed to implement various setpoints for controlling the RF signal control circuit 166, the RF bias control circuit 172, and the RF signal control circuit 182. The setpoints can be implemented in the RF signal control circuits 166, 182 and the RF bias control circuit 172 to implement and/or selectively configure the respective control circuit to achieve a corresponding gain and/or phase offset.

Although the focus ring 130 in reference to the processing equipment 100 of FIG. 1 is described as implemented to control plasma in the chamber 102, the focus ring 130 may be implemented in other processing equipment, such as an ICP processing equipment. Aspects described herein can be applicable to other tools and configurations to control plasma.

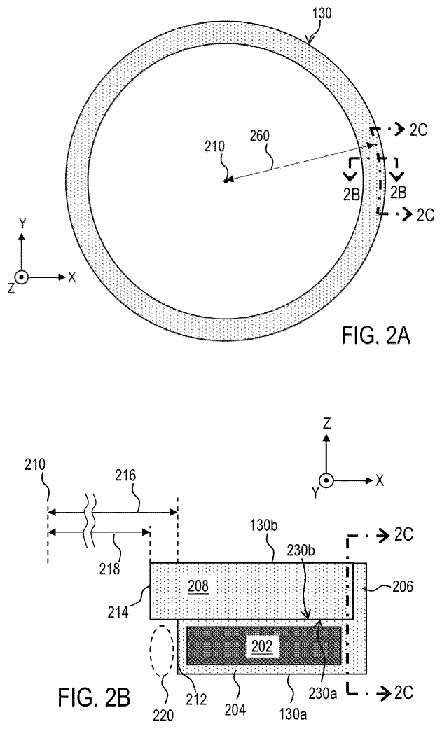

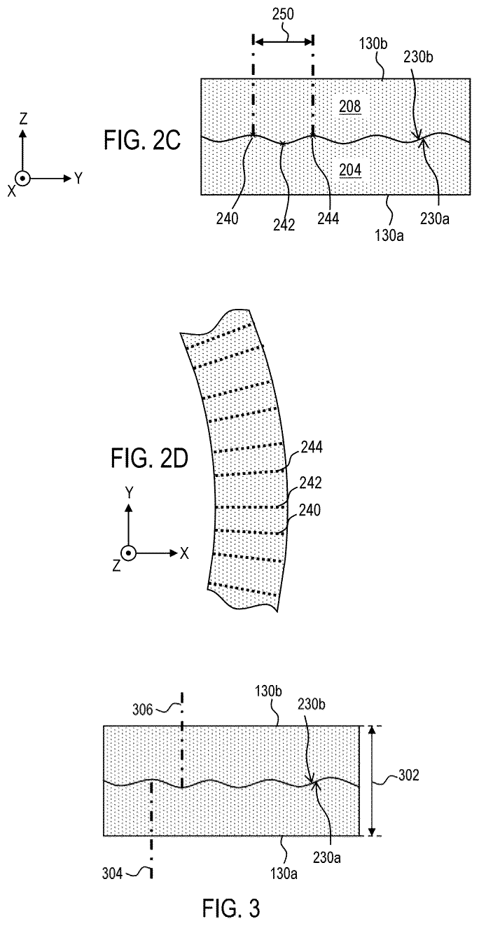

FIG. 2A is a layout view of the focus ring 130 according to some embodiments. FIG. 2A shows a cross-section 2B-2B in an x-z plane that is illustrated in FIG. 2B, and shows a cross-section 2C-2C contoured corresponding to the outer circumference of the focus ring 130 (which is in approximately a y-z plane) that is illustrated in FIG. 2C.

Referring to FIG. 2B, the top layer 130b is over and supported by the bottom layer 130a. The bottom layer 130a includes electrode 202. The electrode 202 is electrically coupled to the external electrical connector 186, which is configured to be electrically coupled to the RF signal control circuit 182. A dielectric material 204 coats electrode 202 and also forms a flange 206 that projects vertically (e.g., in a z-direction) along an outer edge of the bottom layer 130a and circumscribing the top layer 130b. The dielectric material 204 can provide electrical isolation of the electrode 202 from direct electrical contact with other components. Flange 206 of the bottom layer 130a can provide lateral confinement of the top layer 130b relative to the bottom layer 130a. As described generally above, the bottom layer 130a may rotate relative to the top layer 130b. When such rotation occurs, flange 206 may laterally confine the top layer 130b within the lateral bounds of the bottom layer 130a to assist in proper engagement between the bottom layer 130a and the top layer 130b.

The top layer 130b may be formed of a dielectric material 208 or any other material resistive to the plasma semiconductor process (e.g., an etch process) to which the focus ring 130 is to be exposed. Embodiment dielectric materials 204, 208 for the bottom layer 130a and the top layer 130b include any non-conductive material, such as aluminum oxide (Al2O3), yttrium oxide (Y2O3), silicon oxide (SiO2), the like, or a combination thereof. The electrode 202 can be formed of any conductive material (e.g., a metal), such as aluminum (Al), copper (Cu), titanium (Ti), tungsten (W), the like, or a combination thereof.

The bottom layer 130a has an inner vertical sidewall 212, and the top layer 130b has an inner vertical sidewall 214. A radial distance 216 is from the inner vertical sidewall 212 of the bottom layer 130a to the center 210 of the focus ring 130. The radial distance 218 is from the inner vertical sidewall 214 of the top layer 130b to the center 210 of the focus ring 130. The radial distance 218 is less than the radial distance 216. The top layer 130b extends inwardly towards the center 210 of the focus ring 130 more than the bottom layer 130a. This further inward extension of the top layer 130b can allow a particle trap 220 to be formed under the inward extension of the top layer 130b along the inner vertical sidewall 212 of the bottom layer 130a. Particle trap 220 may be a region in which particles accumulate. The particles that accumulate in particle trap 220 may result from the surfaces of the bottom layer 130a and top layer 130b that rub together during the relative rotation of the bottom layer 130a. Particle trap 220 may prevent the particles from contaminating plasma semiconductor process.

The bottom layer 130a has an upper surface 230a, and the top layer 130b has a lower surface 230b. The lower surface 230b of the top layer 130b is disposed on, contacts, and is supported by the upper surface 230a of the bottom layer 130a. Cross-section 2C-2C intersects the upper surface 230a and lower surface 230b. FIG. 2C illustrates the cross-section 2C-2C, which is a circumferential cross-section of a portion of the focus ring 130. In the illustrated embodiment of FIG. 2C, the upper surface 230a and lower surface 230b complement each other, and in other embodiments, the upper surface and lower surface may not complement each other, as shown by subsequent figures.

The upper surface 230a and lower surface 230b are periodic circumferentially around the focus ring 130 and have a same period length at a given radial distance 260 (in FIG. 2A) from the center 210 of the focus ring 130. A protrusion/recess radial line 240, a recess/protrusion radial line 242, and a protrusion/recess radial line 244 of the upper surface 230a and lower surface 230b are shown in a period length 250 at the radial distance 260. The protrusion/recess radial line 240, recess/protrusion radial line 242, and protrusion/recess radial line 244 are a protrusion radial line, a recess radial line, and a protrusion radial line, respectively, for the upper surface 230a, and are a recess radial line, a protrusion radial line, and a recess radial line, respectively, for the lower surface 230b. The period length 250 is shown between the protrusion/recess radial lines 240, 244. The period length 250 is symmetric around a midline of the period length 250 (e.g., the recess/protrusion radial line 242).

The protrusion/recess radial line 240, recess/protrusion radial line 242, and protrusion/recess radial line 244 are shown in a layout view of the corresponding portion of the focus ring 130 in FIG. 2D. The layout view in FIG. 2D illustrates the radial nature of the radial lines 240, 242, 244. Additionally, a period of a focus ring generally incorporates the radial nature. A period length along the outer circumference of the focus ring 130 for a given period is greater than a period length along the inner circumference of the focus ring 130 for that same, given period, for example.

The upper surface 230a and lower surface 230b are continuous surfaces between neighboring pairs of a protrusion radial line and a recess radial line. For example, the upper surface 230a from the protrusion/recess radial line 240 to the recess/protrusion radial line 242 is continuous, and from the recess/protrusion radial line 242 to the protrusion/recess radial line 244 is continuous. Additionally, the lower surface 230b from the protrusion/recess radial line 240 to the recess/protrusion radial line 242 is continuous, and from the recess/protrusion radial line 242 to the protrusion/recess radial line 244 is continuous. In the illustrated embodiment, both the upper surface 230a and the lower surface 230b are continuous surfaces between neighboring pairs of a protrusion radial line and a recess radial line, and in other embodiments, one of the upper surface and the lower surface is continuous surfaces between neighboring pairs of a protrusion radial line and a recess radial line, as is shown in subsequent figures.

In the illustrated embodiment, the upper surface 230a and lower surface 230b are continuous surfaces at the protrusion radial lines and recess radial lines (e.g., at the protrusion/recess radial line 240, the recess/protrusion radial line 242, and the protrusion/recess radial line 240), although in other embodiments, the upper surface 230a and lower surface 230b may be discontinuous at the protrusion radial lines and recess radial lines. For example, the upper surface 230a and/or lower surface 230b may be discontinuous at a vertex line (e.g., of a triangular prism), as illustrated subsequently.

In the illustrated embodiment, the upper surface 230a and lower surface 230b are sinusoidal surfaces, although other embodiments contemplate other continuous surfaces having a periodic structure. In further embodiments, upper surface 230a and lower surface 230b are repeating triangular surfaces or another discontinuous surface at protrusion radial lines and recess radial lines.

FIGS. 3 and 4 illustrate height adjustment of the focus ring 130 according to some embodiments. Referring to FIG. 3, the focus ring 130 has a height 302. The height 302 is the smallest height that the focus ring 130 can have. The height 302, for ease of references, is designated as height h0. At the height h0, protrusion radial lines of the upper surface 230a contact respective recess radial lines of the lower surface 230b, and likewise, recess radial lines of the upper surface 230a contact respective protrusion radial lines of the lower surface 230b. Protrusion radial line 304 of the upper surface 230a and protrusion radial line 306 of the lower surface 230b are shown for reference in the positioning of FIG. 3.

In FIG. 4, the focus ring 130 has a height 402. The height 402 is the greatest height that the focus ring 130 can have. The height 402 is the height h0 plus two times the amplitude of the periodic structure of the upper surface 230a and lower surface 230b. At the height 402, protrusion radial lines of the upper surface 230a contact respective protrusion radial lines of the lower surface 230b. Protrusion radial line 304 of the upper surface 230a and protrusion radial line 306 of the lower surface 230b are also shown for reference in the positioning of FIG. 4.

The rotation 404 of the bottom layer 130a is half a period length of the upper surface 230a and lower surface 230b relative to the position of the top layer 130b. Continuing rotation of the bottom layer 130a to a full period relative to the top layer 130b returns to the focus ring having the height 302 in FIG. 3. Continuous rotation of the bottom layer 130a relative to the top layer 130b results in oscillation of the height of the focus ring 130 between the heights 302, 402 without having to have a hard reset of the bottom layer 130a or the top layer 130b for height adjustment.

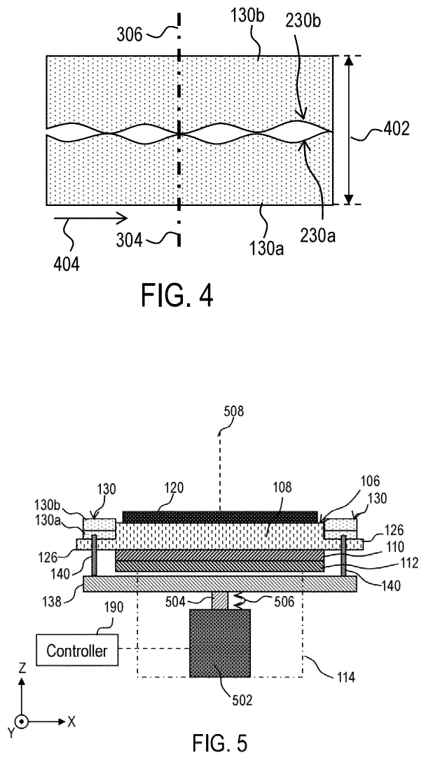

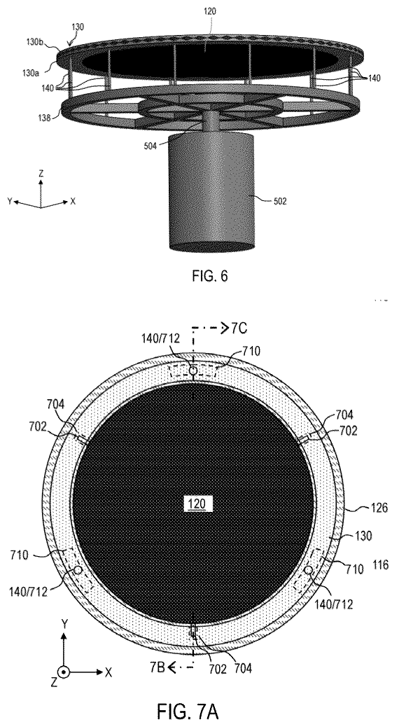

FIG. 5 is a simplified cross-sectional view of the focus ring rotation assembly, and FIG. 6 is a perspective view of the focus ring rotation assembly, according to some embodiments. A semiconductor substrate 120 and the focus ring 130 are shown in FIGS. 5 and 6 for context, as is the substrate support 106, pedestal 114, and controller 190 in FIG. 5. The focus ring rotation assembly further includes a motor 502 having a drive shaft 504. In some embodiments, the motor 502 is a stepper motor, and in other embodiments, the motor 502 can be another type of motor. Motor 502 is configured to rotate 506 the drive shaft 504 around a vertical axis 508 (e.g., a z-direction) that is normal to the top surface of the semiconductor substrate 120 and/or the support surface 116. The rotatable frame 138 is mechanically attached to and supported by the drive shaft 504. As stated previously, the rotation pins 140 are supported by and extend vertically from the rotatable frame 138. The rotation pins 140 extend through respective slots through the flange 126 of the ESC 108 and engage the bottom layer 130a of the focus ring 130. The motor 502 is communicatively coupled to the controller 190, and the controller 190 is configured to control operation of the motor 502.

In operation, the motor 502 causes rotation 506 of the drive shaft 504 around the vertical axis 508, which corresponds, in this embodiment, to an axis of the drive shaft 504. Rotation 506 of the drive shaft 504 causes the rotatable frame 138 to rotate around the vertical axis 508. The mechanical coupling between the rotatable frame 138 and the bottom layer 130a of the focus ring 130 by the rotation pins 140 causes the bottom layer 130a to rotate around the vertical axis 508 when the rotatable frame 138 rotates around the vertical axis 508.

The substrate support 106 (e.g., the ESC 108) that supports the focus ring 130 further includes a stop mechanism that prevents rotation of the top layer 130b of the focus ring 130 when the bottom layer 130a of the focus ring 130 rotates. In some embodiments, the stop mechanism include pins that extend laterally from a sidewall of the substrate support 106 (e.g., the ESC 108) into the top layer 130b. In some embodiments, the stop mechanism include pins that extend vertically from an upper surface of the substrate support 106 (e.g., the ESC 108) that supports the focus ring 130.

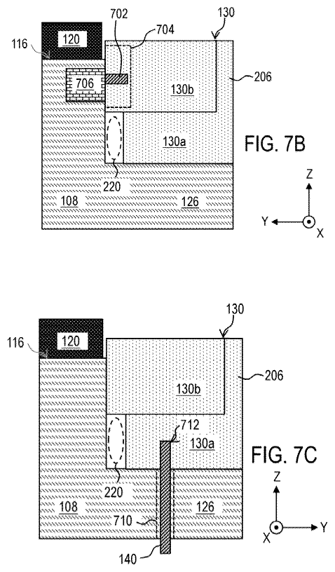

FIG. 7A is a layout view of the focus ring 130 on the flange 126 of the ESC 108 according to some embodiments. In this embodiment, a stop mechanism includes stop pins 702 that extend laterally from a vertical sidewall of the substrate support 106 (e.g., the ESC 108) into respective slots 704 in the top layer 130b. The embodiment of FIG. 7A includes three stop pins 702, although other numbers of stop pins may be used. FIG. 7A further shows rotation pins 140 extending vertically through respective circumferential slots 710 through the flange 126 of the ESC 108 to engage respective recesses 712 in the bottom layer 130a of the focus ring 130. The embodiment of FIG. 7A includes three rotation pins 140, although other numbers of pins may be used (e.g., as shown in previous figures). FIG. 7A shows a cross-section 7B through a stop pin 702 and a cross-section 7C through a rotation pin 140. FIG. 7B illustrates cross-section 7B in further detail, and FIG. 7C illustrates cross-section 7C in further detail.

For context in FIGS. 7A through 7C, as described previously, the semiconductor substrate 120 is disposed on and is supported by the support surface 116 of the substrate support 106 (e.g., the ESC 108), and the ESC 108 includes a flange 126 on which the focus ring 130 is disposed. The focus ring 130, including the bottom layer 130a and top layer 130b, is disposed laterally encircling the semiconductor substrate 120.

Referring to FIGS. 7A and 7B, the ESC 108 includes, for each stop pin 702, an actuator 706 at a sidewall of the ESC 108 extending above flange 126. The actuator 706 is mechanically coupled to the stop pin 702 to project and retract the stop pin 702. In a retracted position, the stop pin 702 does not engage slot 704 in the top layer 130b of the focus ring 130. In a projected position, the stop pin 702 engages slot 704, as is shown in FIG. 7B. The slot 704 has a lateral depth (e.g., along a y-direction in FIG. 7B) from an inner sidewall of the top layer 130b of the focus ring 130 sufficient to accommodate the stop pin 702 in the projected position. The lateral depth is along a radial direction from the center of the focus ring 130 to an edge of the focus ring 130 that intersects the slot 704. The slot 704 has a lateral width (e.g., along an x-direction in FIG. 7B) that is generally the corresponding lateral width of the stop pin 702 (e.g., plus any tolerance). The lateral width is in a plane parallel to the support surface 116 and perpendicular to the radial direction from the center of the focus ring 130 to an edge of the focus ring 130 that intersects the slot 704. The slot 704 has a vertical length (e.g., along a z-direction in FIG. 7B) that generally corresponds to the vertical travel distance that the top layer 130b may be vertically translated resulting from the rotation of the bottom layer 130a. The vertical length is in a plane perpendicular to the support surface 116 and in the radial direction from the center point of the focus ring 130 to the edge of the focus ring 130 that intersects slot 704.

Referring to FIGS. 7A and 7C, for each rotation pin 140, the rotation pin 140 extends vertically through a respective circumferential slot 710 through the flange 126 to engage a respective recess 712 in a bottom surface of the bottom layer 130a of the focus ring 130. The circumferential slot 710 has a lateral circumferential length (e.g., in an x-y plane) that corresponds to a permitted rotational travel distance of the rotation pin 140 and the bottom layer 130a. The lateral circumferential length is along an arc that is perpendicular to respective radial directions that intersect the arc. The circumferential slot 710 has a lateral width (e.g., along a radial direction) that is generally the corresponding lateral width of the rotation pin 140 (e.g., plus any tolerance). Recess 712 has a vertical depth (e.g., in a z-direction) from the bottom surface of the bottom layer 130a. The bottom surface of the bottom layer 130a contacts and is supported by an upper surface of the flange 126. The vertical depth of the recess 712 is sufficient to accommodate the rotation pin 140 engaging the recess 712, e.g., without the rotation pin 140 supporting vertically the bottom layer 130a. Recess 712 has lateral dimensions (e.g., in an x-direction and in a y-direction) that are generally the corresponding lateral dimensions of the rotation pin 140 (e.g., plus any tolerance).

In operation, rotation of the rotatable frame 138 (as described previously) causes the rotation pins 140 to be translated circumferentially in the circumferential slots 710. This translation of the rotation pins 140, which are engaged to recesses 712 in the bottom layer 130a, cause the bottom layer 130a to rotate around the axis of rotation of the rotatable frame 138, which may correspond to the center of the support surface 116. With the stop pin 702 in the projected position and engaging the slot 704, the top layer 130b is prevented from significant rotation with the bottom layer 130a, and hence, the bottom layer 130a rotates relative to the top layer 130b (and the ESC 108). With the rotation of the bottom layer 130a relative to the top layer 130b, the top layer 130b may be translated vertically, such that the stop pin 702 may travel vertically in slot 704. As described with respect to FIGS. 3 and 4, the relative rotation of the bottom layer 130a and the vertical traveling of the top layer 130b can cause a height of the focus ring 130 to be varied.

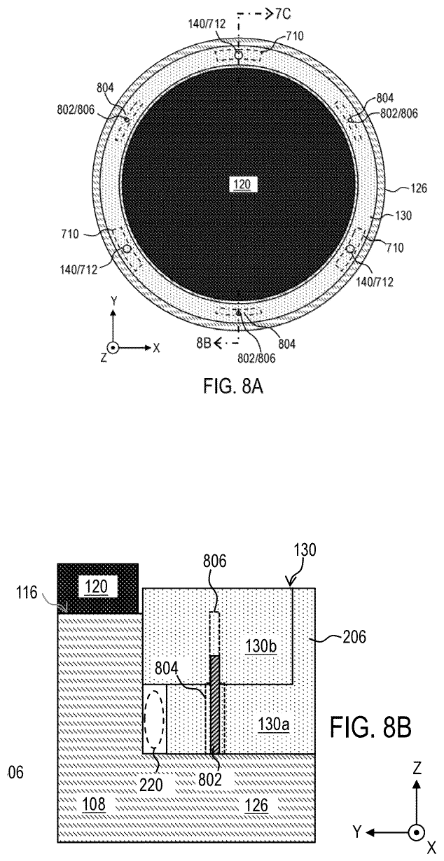

FIG. 8A is a layout view of the focus ring 130 on the flange 126 of the ESC 108 according to some embodiments. In this embodiment, a stop mechanism includes stop pins 802 that extend vertically from an upper surface of the flange 126 through respective circumferential slots 804 through the bottom layer 130a and into a respective recess 806 in the top layer 130b. The embodiment of FIG. 8A includes three stop pins 802, although other numbers of stop pins may be used. FIG. 8A further shows rotation pins 140, like in FIG. 7A. FIG. 8A shows a cross-section 8B through a stop pin 802 and a cross-section 7C through a rotation pin 140. FIG. 8B illustrates cross-section 8B in further detail, and FIG. 7C illustrates cross-section 7C, as described above. Description of features in FIGS. 8A and 8B that are like features described above with respect to FIGS. 7A through 7C is omitted here for brevity.

Referring to FIGS. 8A and 8B, the stop pins 802 extend vertically from the upper surface of flange 126 that contacts and supports the focus ring 130 (e.g., the bottom layer 130a). The stop pins 802 may be static in the embodiment of FIGS. 8A and 8B. The circumferential slot 804 has a lateral circumferential length (e.g., in an x-y plane) that corresponds to a permitted lateral rotational travel distance of the bottom layer 130a relative to flange 126. The lateral circumferential length is along an arc that is perpendicular to respective radial directions that intersect the arc. The circumferential slot 804 has a lateral width (e.g., along a radial direction) that is generally the corresponding lateral width of the stop pin 802 (e.g., plus any tolerance). The recess 806 has a vertical depth (e.g., in a z-direction) from the lower surface 230b of the top layer 130b. The vertical depth of recess 806 is sufficient to accommodate the stop pin 802 engaging the recess 806 as the top layer 130b translates vertically between different heights of the focus ring 130. Additionally, the stop pin 802 has a vertical height that sufficiently extends through the circumferential slot 804 in the bottom layer 130a and engages the recess 806 in the top layer 130b at each height at which the focus ring 130 can achieve (which may be limited by, e.g., a travel distance of a rotation pin 140 in conjunction with the structure of the upper surface 230a and lower surface 230b). The recess 806 has lateral dimensions (e.g., in an x-direction and in a y-direction) that is generally the corresponding lateral dimensions of the stop pin 802 (e.g., plus any tolerance).

In operation, rotation of the rotatable frame 138 (as described previously) causes the rotation pins 140 to be translated circumferentially in the circumferential slots 710. This translation of the rotation pins 140, which are engaged to recesses 712 in the bottom layer 130a, cause the bottom layer 130a to rotate around the axis of rotation of the rotatable frame 138, which may correspond to the center of the support surface 116. With the stop pin 802 engaging the recess 806, the top layer 130b is prevented from significant rotation with the bottom layer 130a, and hence, the bottom layer 130a rotates relative to the top layer 130b (and the flange 126 of the ESC 108). With the rotation of the bottom layer 130a relative to the top layer 130b, the top layer 130b may be translated vertically, such that the recess 806 is translated vertically relative to the stop pin 802. As described with respect to FIGS. 3 and 4, the relative rotation of the bottom layer 130a and the vertical traveling of the top layer 130b can cause a height of the focus ring 130 to be varied.

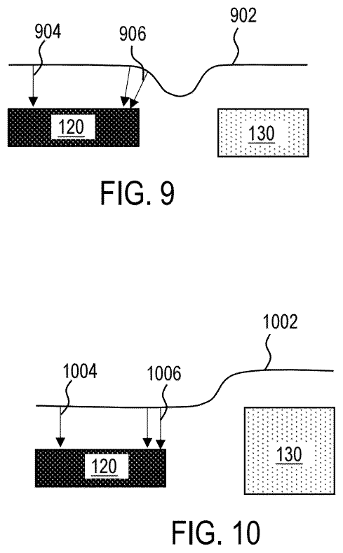

FIGS. 9 and 10 illustrate conceptually how height of the focus ring 130 can contribute to plasma control according to some embodiments. FIGS. 9 and 10 are cross-sectional views of the semiconductor substrate 120 and the focus ring 130 (as disposed in the processing equipment 100 in FIG. 1). In FIG. 9, the focus ring 130 has the height 302 of FIG. 3, and in FIG. 10, the focus ring 130 has the height 402 of FIG. 4, for example. Referring to FIG. 9, plasma sheath 902 dips into the gap between an edge of the semiconductor substrate 120 and the focus ring 130. The plasma sheath 902 is generally flat at a center of the semiconductor substrate 120, and hence, ion bombardment 904 from the plasma on the center of the semiconductor substrate 120 can be generally normal to the top surface of the semiconductor substrate 120. At the edge of the semiconductor substrate 120, the plasma sheath 902 is curved as the plasma sheath dips into the gap, and hence, ion bombardment 906 from the plasma at the edge of the semiconductor substrate 120 can be generally off-normal (e.g., some angle from normal) to the top surface of the semiconductor substrate 120. Referring to FIG. 10, increasing the height of the focus ring 130 can cause the plasma sheath 1002 to extend more flatly beyond the edge of the semiconductor substrate 120. Hence, ion bombardment 1004 at the center of the semiconductor substrate 120 and ion bombardment 1006 at the edge of the semiconductor substrate 120 can both be generally normal to the top surface of the semiconductor substrate 120.

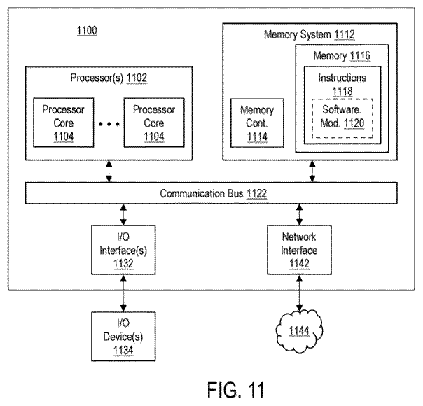

FIG. 11 illustrates a processor-based system 1100 according to some embodiments. The processor-based system 1100 can be or include a computer, a server, a PLC, the like, or a combination thereof. The processor-based system 1100 may be implemented as the controller 190 or as any other processor-based system to implement any operations described herein. The processor-based system 1100 includes one or more processors 1102, a memory system 1112, a communication bus 1122, one or more input/output (I/O) interfaces 1132, and a network interface 1142.

Each processor 1102 can include one or more processor cores 1104. Each processor 1102 and/or processor core 1104 may be, for example, a hardened processor, such as a central processing unit (CPU), a reduced instruction set computing (RISC) processor, a complex instruction set computing (CISC) processor, a graphics processing unit (GPU), a digital signal processor (DSP), an application specific integrated circuit (ASIC), the like, or a combination thereof, or a soft processor implemented on programmable logic, such as a FPGA.

The memory system 1112 includes one or more memory controllers 1114 and memory 1116. Memory controllers 1114 are configured to control read and/or write access to a particular memory 1116 or subset of memory 1116. Memory 1116 may include main memory, disk storage, or any suitable combination thereof. The memory 1116 may include any type of volatile or nonvolatile memory, such as dynamic random access memory (DRAM), static random access memory (SRAM), erasable programmable read-only memory (EPROM), electrically erasable programmable read-only memory (EEPROM), Flash memory, solid-state storage, etc. Memory 1116 is a non-transitory machine-readable storage medium.

Instructions 1118 are stored in memory 1116. The instructions 1118 may be machine-executable code (e.g., machine code) and may comprise firmware, software, a program, an application, or other machine-executable code. The instructions 1118 can, for example, embody a software module 1120, which when executed by the one or more processors 1102, performs various functionality and operations described herein.

The one or more I/O interfaces 1132 are configured to be electrically and/or communicatively coupled to one or more I/O devices 1134. The I/O devices 1134 include the RF signal control circuit 166, the RF bias control circuit 172, the RF signal control circuit 182, and the motor 502. The RF signal control circuit 166, the RF bias control circuit 172, the RF signal control circuit 182, and the motor 502 can receive respective setpoints via the I/O interface 1132. Other embodiment I/O devices 1134 include a keyboard, a mouse, a display device, a printer, etc. The one or more I/O interfaces 1132 can include connectors or coupling circuitry, such as an industrial application connection, a universal serial bus (USB) connection, a high-definition multimedia interface (HDMI) connection, Bluetooth® circuitry, or the like.

The network interface 1142 is configured to be communicatively coupled to a network 1144. The network interface 1142 can include circuitry for wired communication, such as an Ethernet connection, and/or can include circuitry for wireless communication, such as a circuitry for Wi-Fi® communications. For example, one or more computers and/or servers communicatively coupled to the network 1144 may communicate a recipe, process conditions, or the like to the processor-based system 1100 via the network 1144 and the network interface 1142.

The communication bus 1122 is communicatively connected to one or more processors 1102, the memory system 1112, the one or more I/O interfaces 1132, and the network interface 1142. The various components can communicate between each other via the communication bus 1122. The communication bus 1122 can control the flow of communications, such as by including an arbiter to arbitrate the communications.

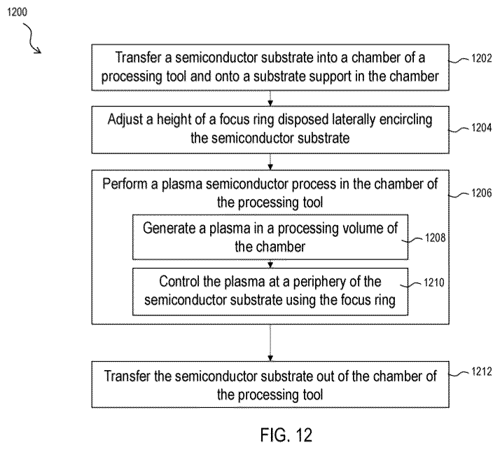

FIG. 12 is a flow chart of a method 1200 of semiconductor processing according to some embodiments. Method 1200 can be implemented using the processing equipment 100 previously described. The operations of method 1200 can be initiated and/or controlled by the controller 190 (e.g., by execution of instructions 1118 by the one or more processors 1102). At block 1202, a semiconductor substrate 120 is transferred into chamber 102 of processing equipment 100 and onto a substrate support 106 (e.g., an ESC 108) in the chamber 102. The focus ring 130 can be disposed on flange 126 of the ESC 108 as the semiconductor substrate 120 is transferred into the chamber 102. The focus ring 130 can be at the smallest height h0. The semiconductor substrate 120 can be secured to the ESC 108 by applying a DC voltage to the chucking electrodes 122 (e.g., to chuck the semiconductor substrate 120). The DC voltage can be generated by DC power supply 160 and applied to the chucking electrodes 122. With the semiconductor substrate 120 transferred into chamber 102 and disposed on the support surface 116, the focus ring 130 is disposed laterally encircling the semiconductor substrate 120.

At block 1204, the height of the focus ring 130 is adjusted. The height can be adjusted to a target height to control plasma in a target manner. The height can be adjusted by rotating the bottom layer 130a relative to the top layer 130b as described above. The controller 190 can cause the motor 502 to rotate the rotatable frame 138, which causes the bottom layer 130a to rotate relative to the top layer 130b. This, in turn, adjusts the height of the focus ring 130.

At block 1206, plasma semiconductor process is performed in chamber 102 of the processing equipment 100. The plasma semiconductor process can be, for example, an etch process, a deposition process, or any other applicable process. Embodiment plasma semiconductor processes include sputtering, PVD, MDP, PECVD, IBE, and RIE. Block 1206 includes, at block 1208, generating plasma in the processing volume 154 of the chamber 102. The semiconductor substrate 120 can be exposed to plasma in the processing volume 154. The plasma can be generated by flowing a gas into chamber 102 (e.g., from the gas supply system 148 and through the gas inlet 146, gas distribution plate 142, and gas showerhead 144) and applying an RF signal to the RF electrode 132. The plasma can be generated as a result of the RF signal on the RF electrode 132 and the gas showerhead 144 being grounded. Block 1206 further includes, at block 1210, controlling the plasma at a periphery of the semiconductor substrate 120. Although described separately for ease, blocks 1208, 1210 can be implemented by the same operation(s). The plasma can be controlled by the RF signal applied to the RF electrode 132. Plasma can be controlled at the periphery using the focus ring 130 based on the height of the focus ring, as described with respect to FIGS. 9 and 10. Additionally, an RF signal can be applied to the electrode 202 of the bottom layer 130a of the focus ring 130 to control the plasma at the periphery of the semiconductor substrate 120. The RF power supply 180 can generate an RF signal that is output to the RF signal control circuit 182, and the RF signal control circuit 182 may adjust the RF signal (to an adjusted amplitude and/or phase) and output the adjusted RF signal. The RF signal output by the RF signal control circuit 182 is applied to electrode 202 of the bottom layer 130a. The RF signal on electrode 202 can, in part, control an electromagnetic field at the periphery of the semiconductor substrate 120 to control the plasma at the periphery. Additionally, biasing of the bias electrode 136 can be performed during blocks 1208, 1210. The biasing can include applying an RF bias signal to the bias electrode 136.

At block 1212, the plasma semiconductor process is concluded, and the semiconductor substrate 120 is transferred out of chamber 102 of the processing equipment 100. At the conclusion of the plasma semiconductor process, the RF signals can cease being applied to the RF electrode 132 and the electrode 202 of the focus ring 130 (e.g., turn off the RF power supplies 164, 180), and gas can cease being supplied into the chamber 102 and can be exhausted out of the chamber 102. Additionally, the RF bias signal can cease being applied to the bias electrode 136. Then, the focus ring 130 can be adjusted back to a smallest height h0. The DC voltage can also be ceased (e.g., by turning off the DC power supply 160) to release the semiconductor substrate 120 from the ESC 108. Thereafter, semiconductor substrate 120 can be transferred out of the chamber 102.

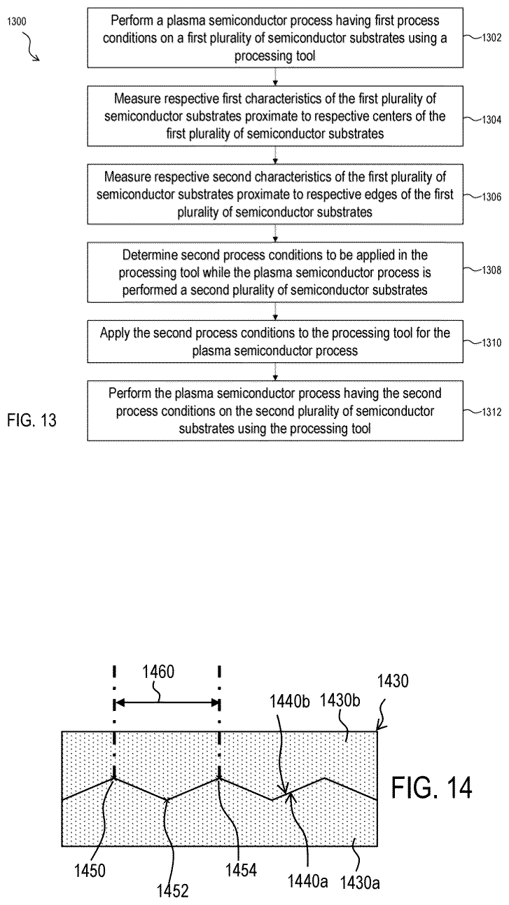

FIG. 13 is a flow chart of a method 1300 for semiconductor processing according to some embodiments. At block 1302, plasma semiconductor process, like described with respect to FIG. 12, is performed on a first plurality of semiconductor substrates (e.g., one or more lots of semiconductor substrates) using processing equipment 100. The plasma semiconductor process is performed having first process conditions. The first process conditions include setpoints of the RF signal control circuit 182 and the motor 502. Based on these setpoints, an RF signal is applied to electrode 202 of the focus ring 130 during the plasma semiconductor process, and a height of the focus ring 130 is set for the plasma semiconductor process.

At block 1304, respective first characteristics of the first plurality of semiconductor substrates proximate to respective centers of the first plurality of substrates are measured, and at block 1306, respective second characteristics of the first plurality of semiconductor substrates proximate to respective edges of the first plurality of substrates are measured. The first characteristic and the second characteristics can be a same feature or component; the use of “first” and “second” is for ease of reference. The measuring can be performed by metrology tools. In some embodiments, the first and second characteristics can be or include profile angles of recesses etched by the plasma semiconductor process. In some embodiments, the first and second characteristics can be or include depths of recesses etched by the plasma semiconductor process. In some embodiments, the first and second characteristics can be or include thicknesses of films deposited by the plasma semiconductor process. Other characteristics may be measured. Variation between the first characteristics and the second characteristics can indicate non-uniformity of the plasma in the plasma semiconductor process when the first plurality of substrates were processed.

At block 1308, using one or more processor-based systems, second process conditions to be applied in the processing equipment while the plasma semiconductor process is performed on a second plurality of semiconductor substrates are determined. The second process conditions are determined based on the first characteristics and the second characteristics measured in blocks 1304, 1306, such as differences between the first characteristics and the second characteristics. The second process conditions are respective same types of process conditions as the first process conditions, although the values or data of the first process conditions and the second process conditions may differ. As an embodiment, a processor-based system operating an advanced process control (APC) algorithm may determine an RF signal (including an amplitude and phase) to be applied to the electrode 202 of the focus ring 130, and may determine a height of the focus ring 130. The processor-based system operating the APC algorithm may then determine setpoints at which to set the RF signal control circuit 182 and the motor 502.

At block 1310, the second process conditions are applied to the processing equipment for the plasma semiconductor process. For example, the processor-based system operating the APC algorithm may communicate the second process conditions (e.g., via network 1144) to the controller 190. The controller 190 can reset the recipe of the plasma semiconductor process to have the second process conditions and can communicate the second process conditions (e.g., the setpoints) to the RF signal control circuit 182, which causes the RF signal control circuit 182 to become selectively configured based on the second process conditions, and to the motor 502, which causes the motor 502 to adjust the height of the focus ring 130.

At block 1312, the plasma semiconductor process is performed on the second plurality of semiconductor substrates using the processing equipment 100. The plasma semiconductor process is performed having the second process conditions. Based on the setpoints of the second process conditions, the motor 502 rotates the bottom layer 130a relative to the top layer 130b to implement a height of the focus ring 130, and an RF signal is applied to the electrode 202 during the plasma semiconductor process.

FIGS. 14, 15, 16, 17, and 18 are cross-sectional views of respective focus rings 1430, 1530, 1630, 1730, 1830 according to some embodiments. The cross-sections of these figures are along cross-section 2C-2C of FIG. 2A. The focus rings 1430, 1530, 1630, 1730, 1830 may be like the focus ring 130 previously described except for an upper surface of the bottom layer and/or lower surface of the top layer of the respective focus ring 1430, 1530, 1630, 1730, 1830.

Referring to FIG. 14, the bottom layer 1430a of the focus ring 1430 has an upper surface 1440a, and the top layer 1430b of the focus ring 1430 has a lower surface 1440b. The lower surface 1440b of the top layer 1430b is disposed on, contacts, and is supported by the upper surface 1440a of the bottom layer 1430a. The upper surface 1440a and lower surface 1440b complement each other. The upper surface 1440a and lower surface 1440b are periodic circumferentially around the focus ring 1430 and have a same period length at a given radial distance from the center of the focus ring 1430. A protrusion/recess radial line 1450, a recess/protrusion radial line 1452, and a protrusion/recess radial line 1454 of the upper surface 1440a and lower surface 1440b are shown in a period length 1460 at a given radial distance from the center of the focus ring 1430. The protrusion/recess radial line 1450, recess/protrusion radial line 1452, and protrusion/recess radial line 1454 are a protrusion radial line, a recess radial line, and a protrusion radial line, respectively, for the upper surface 1440a, and are a recess radial line, a protrusion radial line, and a recess radial line, respectively, for the lower surface 1440b. The period length 1460 is shown between the protrusion/recess radial lines 1450, 1454. The period length 1460 is symmetric around a midline of the period length 1460 (e.g., the recess/protrusion radial line 1452).

The upper surface 1440a and lower surface 1440b are continuous surfaces between neighboring pairs of a protrusion radial line and a recess radial line. For example, the upper surface 1440a from the protrusion/recess radial line 1450 to the recess/protrusion radial line 1452 is continuous, and from the recess/protrusion radial line 1452 to the protrusion/recess radial line 1454 is continuous. Additionally, the lower surface 1440b from the protrusion/recess radial line 1450 to the recess/protrusion radial line 1452 is continuous, and from the recess/protrusion radial line 1452 to the protrusion/recess radial line 1454 is continuous.

In the illustrated embodiment, the upper surface 1440a and lower surface 1440b are discontinuous surfaces at the protrusion radial lines and recess radial lines (e.g., at the protrusion/recess radial line 1450, the recess/protrusion radial line 1452, and the protrusion/recess radial line 1450). In the illustrated embodiment, the upper surface 1440a and lower surface 1440b are surfaces of repeating triangular prisms.

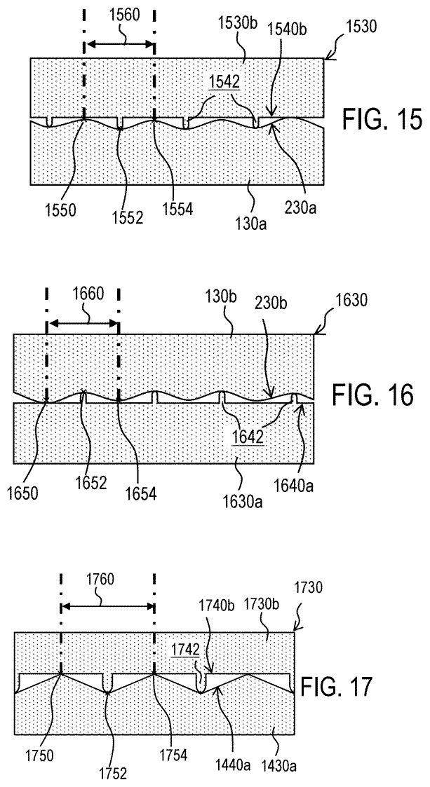

Referring to FIG. 15, the focus ring 1530 has the bottom layer 130a with the upper surface 230a, as previously described. A top layer 1530b has a lower surface 1540b. The lower surface 1540b of the top layer 1530b is disposed on, contacts, and is supported by the upper surface 230a of the bottom layer 130a. The lower surface 1540b is generally a flat surface with protrusions 1542 extending from the flat surface. The lower surface 1540b does not complement the upper surface 230a. The upper surface 230a of the bottom layer 130a is periodic and has a protrusion radial line 1550, a recess radial line 1552, and a protrusion radial line 1554 in a period length 1560 at a given radial distance from the center of the focus ring 1530. The protrusions 1542 of the lower surface 1540b of the top layer 1530b are located with a same period length 1560 at the given radial distance from the center of the focus ring 1530 circumferentially around the focus ring 1530. The period length 1560 in the lower surface 1540b is symmetric around a radial line intersecting a respective protrusion 1542. In this embodiment, the lower surface 1540b is not continuous between neighboring pairs of a protrusion radial line and a recess radial line (e.g., for one arbitrarily located recess radial line on the flat surface, the lower surface 1540b is not continuous to both neighboring protrusion radial lines on either lateral side of the recess radial line).

Referring to FIG. 16, the focus ring 1630 has the top layer 130b with the lower surface 230b, as previously described. A bottom layer 1630a has an upper surface 1640a. The lower surface 230b of the top layer 130b is disposed on, contacts, and is supported by the upper surface 1640a of the bottom layer 1630a. The upper surface 1640a is generally a flat surface with protrusions 1642 extending from the flat surface. The upper surface 1640a does not complement the lower surface 230b. The lower surface 230b of the top layer 130b is periodic and has a protrusion radial line 1650, a recess radial line 1652, and a protrusion radial line 1654 in a period length 1660 at a given radial distance from the center of the focus ring 1530. The protrusions 1642 of the upper surface 1640a of the bottom layer 1630a are located with a same period length 1660 at the given radial distance from the center of the focus ring 1530 circumferentially around the focus ring 1630. The period length 1660 in the upper surface 1640a is symmetric around a radial line intersecting a respective protrusion 1642. In this embodiment, the upper surface 1640a is not continuous between neighboring pairs of a protrusion radial line and a recess radial line (e.g., for one arbitrarily located recess radial line on the flat surface, the upper surface 1640a is not continuous to both neighboring protrusion radial lines on either lateral side of the recess radial line).

Referring to FIG. 17, the focus ring 1730 has the bottom layer 1430a with the upper surface 1440a, as previously described. A top layer 1730b has a lower surface 1740b. The lower surface 1740b of the top layer 1730b is disposed on, contacts, and is supported by the upper surface 1440a of the bottom layer 1430a. The lower surface 1740b is generally a flat surface with protrusions 1742 extending from the flat surface. The lower surface 1740b does not complement the upper surface 1440a. The upper surface 1440a of the bottom layer 1430a is periodic and has a protrusion radial line 1750, a recess radial line 1752, and a protrusion radial line 1754 in a period length 1760 at a given radial distance from the center of the focus ring 1530. The protrusions 1742 of the lower surface 1740b of the top layer 1730b are located with a same period length 1760 at the given radial distance from the center of the focus ring 1530 circumferentially around the focus ring 1730. The period length 1760 in the lower surface 1740b is symmetric around a radial line intersecting a respective protrusion 1742. In this embodiment, the lower surface 1740b is not continuous between neighboring pairs of protrusion radial line and recess radial line (e.g., for one arbitrarily located recess radial line on the flat surface, the lower surface 1740b is not continuous to both neighboring protrusion radial lines on either lateral side of the recess radial line).

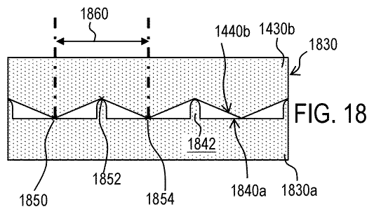

Referring to FIG. 18, the focus ring 1830 has the top layer 1430b with the lower surface 1440b, as previously described. The bottom layer 1830a has an upper surface 1840a. The lower surface 1440b of the top layer 1430b is disposed on, contacts, and is supported by the upper surface 1840a of the bottom layer 1830a. The upper surface 1840a is generally a flat surface with protrusions 1842 extending from the flat surface. The upper surface 1840a does not complement the lower surface 1440b. The lower surface 1440b of the top layer 1430b is periodic and has a protrusion radial line 1850, a recess radial line 1852, and a protrusion radial line 1854 in a period length 1860 at a given radial distance from the center of the focus ring 1530. The protrusions 1842 of the upper surface 1840a of the bottom layer 1830a are located with a same period length 1860 at the given radial distance from the center of the focus ring 1530 circumferentially around the focus ring 1830. The period length 1860 in the upper surface 1840a is symmetric around a radial line intersecting a respective protrusion 1842. In this embodiment, the upper surface 1840a is not continuous between neighboring pairs of a protrusion radial line and a recess radial line (e.g., for one arbitrarily located recess radial line on the flat surface, the upper surface 1840a is not continuous to both neighboring protrusion radial lines on either lateral side of the recess radial line).

The various upper and lower surfaces of bottom and top layers of a focus ring have been provided as embodiments. Other modifications and configurations can be implemented for upper and lower surfaces of bottom and top layers of a focus ring according to other embodiments.

A first embodiment is a component for semiconductor processing. The component includes a focus ring configured to laterally encircle a semiconductor substrate during plasma semiconductor process. The focus ring includes a first ring layer having a lower surface and includes a second ring layer having an upper surface. The upper surface is configured to support the first ring layer by the lower surface contacting the upper surface. The lower surface and the upper surface are periodic circumferentially. The lower surface and the upper surface have the same period length at a same first radial distance from a center of the focus ring. At least one of the lower surface and the upper surface includes a first protrusion radial line, a first recess radial line, and a second protrusion radial line. The first recess radial line is disposed laterally between the first protrusion radial line and the second protrusion radial line. The period length at the first radial distance is from the first protrusion radial line to the second protrusion radial line. The at least one of the lower surface and the upper surface from the first protrusion radial line to the first recess radial line is continuous. At least one of the lower surface and the upper surface from the first recess radial line to the second protrusion radial line is continuous. The second ring layer is laterally, rotatably movable relative to the first ring layer while the upper surface supports the first ring layer.

In the first embodiment, the at least one of the lower surface and the upper surface may be continuous at each of the first protrusion radial line, the first recess radial line, and the second protrusion radial line.

In the first embodiment, the at least one of the lower surface and the upper surface may be discontinuous at each of the first protrusion radial line, the first recess radial line, and the second protrusion radial line.

In the first embodiment, the period length at the first radial distance from the first protrusion radial line to the second protrusion radial line may be symmetric around the first recess radial line.

In the first embodiment, the at least one of the lower surface and the upper surface may be a sinusoidal surface. The first protrusion radial line, the first recess radial line, and the second protrusion radial line each may be in the sinusoidal surface.

In the first embodiment, the other of the lower surface and the upper surface may include a second recess radial line, a third protrusion radial line, and a third recess radial line. The third protrusion radial line may be disposed laterally between the second recess radial line and the third recess radial line. The period length at the first radial distance may be from the second recess radial line to the third recess radial line. The other of the lower surface and the upper surface from the second recess radial line to the third protrusion radial line may be continuous. The other of the lower surface and the upper surface from the third protrusion radial line to the third recess radial line may be continuous. Further, in the component, the other of the lower surface and the upper surface may be continuous at each of the second recess radial line, the third protrusion radial line, and the third recess radial line. Further, in the component, the other of the lower surface and the upper surface may be discontinuous at each of the second recess radial line, the third protrusion radial line, and the third recess radial line.

In the first embodiment, the lower surface and the upper surface may each be a sinusoidal surface. The upper surface may be complementary to the lower surface.

In the first embodiment, the first ring layer may be a non-conductive material.

In the first embodiment, the second ring layer may include a conductive electrode.

In the first embodiment, the second ring layer may include a flange projecting vertically, and the flange may be configured to laterally confine the first ring layer.

In the first embodiment, an inner vertical surface of the first ring layer may be at a second radial distance from the center of the focus ring. The inner vertical surface of the second ring layer may be at a third radial distance from the center of the focus ring. The inner vertical surface of the second ring layer may be configured to be under the first ring layer while the lower surface supports the first ring layer. The second radial distance may be less than the third radial distance.

In the first embodiment, the second ring layer may have a bottom surface, and recesses may be in the second ring layer from the bottom surface. The recesses may be configured to have respective pins engaged with the recesses.

In the first embodiment, the first ring layer may have an inner sidewall. Slots may be in the first ring layer from the inner sidewall to a depth in the first ring layer. The slots may be configured to have respective pins engaged with the slots. The slots may further be configured to permit the respective pins to travel vertically within the slots relative to the first ring layer.

In the first embodiment, the second ring layer may have slots through the second ring layer. The slots may be configured to permit respective pins to travel laterally relative to the second ring layer in the slots. The first ring layer may have recesses in the first ring layer from the lower surface. The recesses may be configured to have the respective pins engaged with the recesses. The recesses may further be configured to permit the respective pins to travel vertically within the recesses relative to the first ring layer.

A second embodiment is processing equipment for semiconductor processing. The processing equipment includes a chamber, a substrate support, and a focus ring rotation assembly. The chamber has an internal volume within the chamber. The substrate support is disposed in the internal volume of the chamber. The substrate support has a support surface configured to support a semiconductor substrate. The substrate support includes a flange configured to support a focus ring laterally encircling the support surface. The focus ring rotation assembly is disposed at least partially in the internal volume of the chamber. The focus ring rotation assembly is configured to rotate at least a portion of the focus ring laterally around an axis normal to the support surface. The focus ring rotation assembly includes a frame that is configured to rotate laterally around the axis normal to the support surface.

In the second embodiment, the substrate support may include stop pins at a vertical sidewall of the substrate support above the flange. The stop pins may extend laterally from the vertical sidewall in a projected position. The stop pins may be retractable. The stop pins may be configured to engage respective slots in an inner sidewall of the focus ring. Additionally, the substrate support may include actuators each configured to retract and project a respective stop pin of the stop pins.

In the second embodiment, the substrate support may include stop pins extending vertically from the flange. The stop pins may be configured to engage respective recesses in a lower surface of the focus ring. Further, the stop pins may be static.

In the second embodiment, the focus ring rotation assembly may further include rotation pins. The rotation pins may be mechanically coupled to and projecting from the frame. The rotation pins may extend through respective slots through the flange and may project vertically above the flange configured to engage respective recesses in a bottom surface of the focus ring.

In the second embodiment, the focus ring rotation assembly may further include a motor mechanically coupled to the frame and configured to rotate laterally the frame.

The second embodiment may further include an electrical connector configured to be electrically coupled to the focus ring.

The second embodiment may further include a power supply and a control circuit. The power supply may be configured to output a voltage on an output node of the power supply. The control circuit may have an input node electrically coupled to the output node of the power supply and may have an output node configured to be electrically coupled to the focus ring. The control circuit may be controllable to adjust an amplitude, a phase, or a combination thereof of the voltage and output a corresponding adjusted voltage on the output node of the control circuit. Additionally, the processing equipment may further include a controller. The controller may include one or more processors and non-transitory memory. The non-transitory memory may include stored instructions, which when executed by one or more processors, may cause the one or more processors to control the control circuit to adjust the amplitude, the phase, or combination thereof.

A third embodiment is a method for semiconductor processing. The method includes adjusting the height of a focus ring. The focus ring is disposed laterally encircling a semiconductor substrate in a chamber of processing equipment. The focus ring includes a first ring layer and a second ring layer. Adjusting the height of the focus ring includes rotating the second ring layer relative to the first ring layer. The first ring layer has a lower surface. The second ring layer has an upper surface. The lower surface is disposed on and contacting the upper surface. The lower surface and the upper surface are periodic circumferentially. The lower surface and the upper surface have the same period length at a same first radial distance from a center of the focus ring. At least one of the lower surface and the upper surface includes a first protrusion radial line, a first recess radial line, and a second protrusion radial line. The first recess radial line is disposed laterally between the first protrusion radial line and the second protrusion radial line. The period length at the first radial distance is from the first protrusion radial line to the second protrusion radial line. The at least one of the lower surface and the upper surface from the first protrusion radial line to the first recess radial line is continuous. At least one of the lower surface and the upper surface from the first recess radial line to the second protrusion radial line is continuous. The method includes generating plasma in a processing volume of the chamber while the focus ring is disposed laterally encircling the semiconductor substrate. The semiconductor substrate is exposed to plasma.

In the third embodiment, the at least one of the lower surface and the upper surface may be continuous at each of the first protrusion radial line, the first recess radial line, and the second protrusion radial line.

In the third embodiment, the at least one of the lower surface and the upper surface may be discontinuous at each of the first protrusion radial line, the first recess radial line, and the second protrusion radial line.

In the third embodiment, the period length at the first radial distance from the first protrusion radial line to the second protrusion radial line may be symmetric around the first recess radial line.

In the third embodiment, the at least one of the lower surface and the upper surface may be a sinusoidal surface. The first protrusion radial line, the first recess radial line, and the second protrusion radial line each may be in the sinusoidal surface.

In the third embodiment, the other of the lower surface and the upper surface may include a second recess radial line, a third protrusion radial line, and a third recess radial line. The third protrusion radial line may be disposed laterally between the second recess radial line and the third recess radial line. The period length at the first radial distance may be from the second recess radial line to the third recess radial line. The other of the lower surface and the upper surface from the second recess radial line to the third protrusion radial line may be continuous. The other of the lower surface and the upper surface from the third protrusion radial line to the third recess radial line may be continuous. The other of the lower surface and the upper surface may be continuous at each of the second recess radial line, the third protrusion radial line, and the third recess radial line. In this method, the other of the lower surface and the upper surface may be discontinuous at each of the second recess radial line, the third protrusion radial line, and the third recess radial line.

In the third embodiment, the lower surface and the upper surface may be each a sinusoidal surface. The upper surface may be complementary to the lower surface.

In the third embodiment, the first ring layer may be a non-conductive material.

In the third embodiment, the second ring layer may include a conductive electrode. Additionally, the method may further include applying a voltage to the conductive electrode while the plasma is in the processing volume.

In the third embodiment, the second ring layer may include a flange projecting vertically. The flange may be configured to laterally confine the first ring layer.

In the third embodiment, an inner vertical surface of the first ring layer may be at a second radial distance from the center of the focus ring, and an inner vertical surface of the second ring layer may be at a third radial distance from the center of the focus ring. The inner vertical surface of the second ring layer may be configured to be under the first ring layer while the lower surface supports the first ring layer. The second radial distance may be less than the third radial distance.

In the third embodiment, the semiconductor substrate may be disposed on a substrate support in the chamber of the processing equipment. The substrate support may include a flange. The focus ring may be disposed on the flange. A focus ring rotation assembly may rotate the second ring layer relative to the first ring layer. Additionally, the focus ring rotation assembly may include a frame and rotation pins mechanically coupled to and projecting from the frame. The rotation pins may extend through respective slots through the flange and engage respective recesses in the bottom surface of the focus ring. Rotating the second ring layer relative to the first ring layer may include rotating the frame. Further, the focus ring rotation assembly may include a motor, and the motor may rotate the frame.

The substrate support may include stop pins at a vertical sidewall of the substrate support above the flange. Rotating the second ring layer relative to the first ring layer may include engaging the stop pins in respective slots in an inner sidewall of the first ring layer. Additionally, in this method the stop pins may be retractable.

The substrate support may include stop pins extending vertically from the flange. Rotating the second ring layer relative to the first ring layer may include extending the stop pins through respective slots through the second ring layer, and engaging the stop pins in respective recesses in the lower surface of the first ring layer. Additionally, the stop pins may be static.

A fourth embodiment is a method for semiconductor processing. The method includes performing plasma semiconductor process having first process conditions on a first plurality of substrates using processing equipment. The processing equipment includes a substrate support configured to support a substrate during the plasma semiconductor process. A focus ring is disposed laterally encircling the substrate during the plasma semiconductor process. The focus ring has a first ring layer and a second ring layer supporting and contacting the first ring layer. The height of the focus ring is adjustable by rotating the second ring layer relative to the first ring layer. The first process conditions correspond to a first amount of rotation of the second ring layer relative to the first ring layer to implement a first height of the focus ring during the plasma semiconductor process. The method includes measuring respective first characteristics of the first plurality of substrates proximate to respective centers of the first plurality of substrates. The first characteristics are formed by the plasma semiconductor process. The method includes measuring respective second characteristics of the first plurality of substrates proximate to respective edges of the first plurality of substrates. The second characteristic is formed by the plasma semiconductor process. The method includes, by a processor-based system, determining second process conditions to be applied while performing the plasma semiconductor process on a second plurality of substrates based on the first characteristics and the second characteristics. The second process conditions correspond to a second amount of rotation of the second ring layer relative to the first ring layer to implement a second height of the focus ring during the plasma semiconductor process. The method includes performing the plasma semiconductor process having the second process conditions on the second plurality of substrates using the processing equipment.

In the fourth embodiment, the first characteristics may include, for each substrate of the first plurality of substrates, a first profile angle of a recess etched into the respective substrate proximate a respective center of the respective substrate, and the second characteristics may include, for each substrate of the first plurality of substrates, a second profile angle of a recess etched into the respective substrate proximate a respective edge of the respective substrate.

In the fourth embodiment, the first characteristics may include, for each substrate of the first plurality of substrates, a first depth of a recess etched into the respective substrate proximate a respective center of the respective substrate, and the second characteristics may include, for each substrate of the first plurality of substrates, a second depth of a recess etched into the respective substrate proximate a respective edge of the respective substrate.

In the fourth embodiment, the first characteristics may include, for each substrate of the first plurality of substrates, a first thickness of a film deposited on the respective substrate proximate a respective center of the respective substrate, and the second characteristics may include, for each substrate of the first plurality of substrates, a second thickness of the film proximate a respective edge of the respective substrate.

In the fourth embodiment, performing the plasma semiconductor process having first process conditions on the first plurality of substrates may further have third process conditions. The third process conditions may correspond to a first amplitude and a first phase of a signal applied to an electrode of the focus ring during the plasma semiconductor process. Determining the second process conditions may further include determining fourth process conditions to be applied while performing the plasma semiconductor process on the second plurality of substrates based on the first characteristics and the second characteristics. The fourth process conditions may correspond to a second amplitude and a second phase of a signal applied to the electrode of the focus ring during the plasma semiconductor process. Performing the plasma semiconductor process having the second process conditions on the second plurality of substrates may further have the fourth process conditions.

Although various embodiments have been described in detail, it should be understood that various changes, substitutions, and alterations can be made therein without departing from the scope defined by the appended claims.

What is claimed is:

1. A component for semiconductor processing, the component comprising:
a focus ring configured to laterally encircle a semiconductor substrate during plasma semiconductor process, the focus ring comprising:
a first ring layer having a lower surface; and
a second ring layer having an upper surface, the upper surface being configured to support the first ring layer by the lower surface contacting the upper surface, wherein:
the lower surface and the upper surface are periodic circumferentially;
the lower surface and the upper surface have a same period length at a same first radial distance from a center of the focus ring;
at least one of the lower surface and the upper surface comprises a first protrusion radial line, a first recess radial line, and a second protrusion radial line, the first recess radial line being disposed laterally between the first protrusion radial line and the second protrusion radial line;
the period length at the first radial distance is from the first protrusion radial line to the second protrusion radial line;
the at least one of the lower surface and the upper surface from the first protrusion radial line to the first recess radial line is continuous;
the at least one of the lower surface and the upper surface from the first recess radial line to the second protrusion radial line is continuous; and
the second ring layer is laterally, rotatably movable relative to the first ring layer while the upper surface supports the first ring layer.

2. The component of claim 1, wherein the at least one of the lower surface and the upper surface is continuous at each of the first protrusion radial line, the first recess radial line, and the second protrusion radial line.

3. The component of claim 1, wherein the at least one of the lower surface and the upper surface is discontinuous at each of the first protrusion radial line, the first recess radial line, and the second protrusion radial line.

4. The component of claim 1, wherein the period length at the first radial distance from the first protrusion radial line to the second protrusion radial line is symmetric around the first recess radial line.

5. The component of claim 1, wherein the at least one of the lower surface and the upper surface is a sinusoidal surface, the first protrusion radial line, the first recess radial line, and the second protrusion radial line each being on the sinusoidal surface.

6. The component of claim 1, wherein:
the other of the lower surface and the upper surface comprises a second recess radial line, a third protrusion radial line, and a third recess radial line, the third protrusion radial line being disposed laterally between the second recess radial line and the third recess radial line;
the period length at the first radial distance being from the second recess radial line to the third recess radial line;
the other of the lower surface and the upper surface from the second recess radial line to the third protrusion radial line being continuous; and
the other of the lower surface and the upper surface from the third protrusion radial line to the third recess radial line being continuous.

7. The component of claim 6, wherein the other of the lower surface and the upper surface is continuous at each of the second recess radial line, the third protrusion radial line, and the third recess radial line.

8. The component of claim 6, wherein the other of the lower surface and the upper surface is discontinuous at each of the second recess radial line, the third protrusion radial line, and the third recess radial line.

9. The component of claim 1, wherein the lower surface and the upper surface are each a sinusoidal surface, the upper surface being complementary to the lower surface.

10. The component of claim 1, wherein the first ring layer is a non-conductive material.

11. The component of claim 1, wherein the second ring layer comprises a conductive electrode.

12. The component of claim 1, wherein the second ring layer includes a flange projecting vertically, the flange being configured to laterally confine the first ring layer.

13. The component of claim 1, wherein:
an inner vertical surface of the first ring layer is at a second radial distance from the center of the focus ring;
an inner vertical surface of the second ring layer is at a third radial distance from the center of the focus ring, the inner vertical surface of the second ring layer being configured to be under the first ring layer while the lower surface supports the first ring layer; and
the second radial distance is less than the third radial distance.

14. The component of claim 1, wherein the second ring layer has a bottom surface, recesses being in the second ring layer from the bottom surface, the recesses being configured to have respective pins engaged with the recesses.

15. The component of claim 1, wherein the first ring layer has an inner sidewall, slots being in the first ring layer from the inner sidewall to a depth in the first ring layer, the slots being configured to have respective pins engaged with the slots, the slots further being configured to permit the respective pins to travel vertically within the slots relative to the first ring layer.

16. The component of claim 1, wherein:
the second ring layer has slots through the second ring layer, the slots being configured to permit respective pins to travel laterally relative to the second ring layer in the slots; and
the first ring layer has recesses in the first ring layer from the lower surface, the recesses being configured to have the respective pins engaged with the recesses, the recesses further being configured to permit the respective pins to travel vertically within the recesses relative to the first ring layer.

17. Processing equipment for semiconductor processing, the processing equipment comprising:
a chamber having an internal volume within the chamber;
a substrate support disposed inside the chamber, the substrate support having a support surface configured to support a semiconductor substrate, the substrate support comprising a flange configured to support a focus ring laterally encircling the support surface; and
a focus ring rotation assembly disposed at least partially inside the chamber, the focus ring rotation assembly being configured to rotate at least a portion of the focus ring laterally around an axis normal to the support surface, the focus ring rotation assembly comprising a frame that is configured to rotate laterally around the axis normal to the support surface.

18. The processing equipment of claim 17, wherein the substrate support comprises stop pins at a vertical sidewall of the substrate support above the flange, the stop pins extending laterally from the vertical sidewall in a projected position, the stop pins being retractable, the stop pins being configured to engage respective slots in an inner sidewall of the focus ring.

19. The processing equipment of claim 18, wherein the substrate support comprises actuators each configured to retract and project a respective stop pin of the stop pins.

20. The processing equipment of claim 17, wherein the substrate support comprises stop pins extending vertically from the flange, the stop pins being configured to engage respective recesses in a lower surface of the focus ring.

21. The processing equipment of claim 20, wherein the stop pins are static.

22. The processing equipment of claim 17, wherein the focus ring rotation assembly further comprising rotation pins, the rotation pins being mechanically coupled to and projecting from the frame, the rotation pins extending through respective slots through the flange and projecting vertically above the flange configured to engage respective recesses in a bottom surface of the focus ring.

23. The processing equipment of claim 17, wherein the focus ring rotation assembly further comprises a motor mechanically coupled to the frame and configured to rotate laterally the frame.

24. The processing equipment of claim 17 further comprising an electrical connector configured to be electrically coupled to the focus ring.

25. The processing equipment of claim 17 further comprising:
a power supply configured to output a voltage on an output node of the power supply; and
a control circuit having an input node electrically coupled to the output node of the power supply and having an output node configured to be electrically coupled to the focus ring, the control circuit being controllable to adjust an amplitude, a phase, or a combination thereof of the voltage and output a corresponding adjusted voltage on the output node of the control circuit.

26. The processing equipment of claim 25 further comprising:
a controller comprising:
one or more processors; and
non-transitory memory comprising stored instructions, which when executed by the one or more processors, cause the one or more processors to control the control circuit to adjust the amplitude, the phase, or combination thereof.

27. A method for semiconductor processing, the method comprising:
adjusting a height of a focus ring, the focus ring being disposed laterally encircling a semiconductor substrate in a chamber of processing equipment, the focus ring comprising a first ring layer and a second ring layer; and
generating plasma in the chamber while the focus ring is disposed laterally encircling the semiconductor substrate, the semiconductor substrate being exposed to the plasma;
wherein adjusting the height of the focus ring comprising rotating the second ring layer relative to the first ring layer, and
the first ring layer has a lower surface;
the second ring layer has an upper surface, the lower surface being disposed on and contacting the upper surface;
the lower surface and the upper surface are periodic circumferentially;
the lower surface and the upper surface have a same period length at a same first radial distance from a center of the focus ring;
at least one of the lower surface and the upper surface comprises a first protrusion radial line, a first recess radial line, and a second protrusion radial line, the first recess radial line being disposed laterally between the first protrusion radial line and the second protrusion radial line;
the period length at the first radial distance is from the first protrusion radial line to the second protrusion radial line;
the at least one of the lower surface and the upper surface from the first protrusion radial line to the first recess radial line is continuous; and
the at least one of the lower surface and the upper surface from the first recess radial line to the second protrusion radial line is continuous.

28. The method of claim 27, wherein the at least one of the lower surface and the upper surface is continuous at each of the first protrusion radial line, the first recess radial line, and the second protrusion radial line.

29. The method of claim 27, wherein the at least one of the lower surface and the upper surface is discontinuous at each of the first protrusion radial line, the first recess radial line, and the second protrusion radial line.

30. The method of claim 27, wherein the period length at the first radial distance from the first protrusion radial line to the second protrusion radial line is symmetric around the first recess radial line.

31. The method of claim 27, wherein the at least one of the lower surface and the upper surface is a sinusoidal surface, the first protrusion radial line, the first recess radial line, and the second protrusion radial line each being in the sinusoidal surface.

32. The method of claim 27, wherein:
the other of the lower surface and the upper surface comprises a second recess radial line, a third protrusion radial line, and a third recess radial line, the third protrusion radial line being disposed laterally between the second recess radial line and the third recess radial line;
the period length at the first radial distance being from the second recess radial line to the third recess radial line;
the other of the lower surface and the upper surface from the second recess radial line to the third protrusion radial line being continuous; and
the other of the lower surface and the upper surface from the third protrusion radial line to the third recess radial line being continuous.

33. The method of claim 32, wherein the other of the lower surface and the upper surface is continuous at each of the second recess radial line, the third protrusion radial line, and the third recess radial line.

34. The method of claim 32, wherein the other of the lower surface and the upper surface is discontinuous at each of the second recess radial line, the third protrusion radial line, and the third recess radial line.

35. The method of claim 27, wherein the lower surface and the upper surface are each a sinusoidal surface, the upper surface being complementary to the lower surface.

36. The method of claim 27, wherein the first ring layer is a non-conductive material.

37. The method of claim 27, wherein the second ring layer comprises a conductive electrode.

38. The method of claim 37 further comprising applying a voltage to the conductive electrode while the plasma is in the chamber.

39. The method of claim 27, wherein the second ring layer includes a flange projecting vertically, the flange being configured to laterally confine the first ring layer.

40. The method of claim 27, wherein:
an inner vertical surface of the first ring layer is at a second radial distance from the center of the focus ring;
an inner vertical surface of the second ring layer is at a third radial distance from the center of the focus ring, the inner vertical surface of the second ring layer being configured to be under the first ring layer while the lower surface supports the first ring layer; and
the second radial distance is less than the third radial distance.

41. The method of claim 27, wherein:
the semiconductor substrate is disposed on a substrate support in the chamber of the processing equipment;
the substrate support comprises a flange, the focus ring being disposed on the flange; and
a focus ring rotation assembly rotates the second ring layer relative to the first ring layer.

42. The method of claim 41, wherein:
the focus ring rotation assembly comprises a frame and rotation pins mechanically coupled to and projecting from the frame;
the rotation pins extend through respective slots through the flange and engage respective recesses in a bottom surface of the focus ring; and
rotating the second ring layer relative to the first ring layer includes rotating the frame.

43. The method of claim 42, wherein the focus ring rotation assembly comprises a motor, the motor rotating the frame.

44. The method of claim 41, wherein:
the substrate support comprises stop pins at a vertical sidewall of the substrate support above the flange; and
rotating the second ring layer relative to the first ring layer includes engaging the stop pins in respective slots in an inner sidewall of the first ring layer.

45. The method of claim 44, wherein the stop pins are retractable.

46. The method of claim 41, wherein:
the substrate support comprises stop pins extending vertically from the flange; and
rotating the second ring layer relative to the first ring layer includes:
extending the stop pins through respective slots through the second ring layer; and
engaging the stop pins in respective recesses in the lower surface of the first ring layer.

47. The method of claim 46, wherein the stop pins are static.

48. A method for semiconductor processing, the method comprising:
performing plasma semiconductor process having first process conditions on a first plurality of substrates using processing equipment, the processing equipment comprising a substrate support configured to support a substrate during the plasma semiconductor process, a focus ring being disposed laterally encircling the substrate during the plasma semiconductor process, the focus ring having a first ring layer and a second ring layer supporting and contacting the first ring layer, a height of the focus ring being adjustable by rotating the second ring layer relative to the first ring layer, the first process conditions corresponding to a first amount of rotation of the second ring layer relative to the first ring layer to implement a first height of the focus ring during the plasma semiconductor process;
measuring respective first characteristics of the first plurality of substrates proximate to respective centers of the first plurality of substrates, the first characteristics being formed by the plasma semiconductor process;
measuring respective second characteristics of the first plurality of substrates proximate to respective edges of the first plurality of substrates, the second characteristics being formed by the plasma semiconductor process;
determining second process conditions to be applied while performing the plasma semiconductor process on a second plurality of substrates based on the first characteristics and the second characteristics, the second process conditions corresponding to a second amount of rotation of the second ring layer relative to the first ring layer to implement a second height of the focus ring during the plasma semiconductor process; and
performing the plasma semiconductor process having the second process conditions on the second plurality of substrates using the processing equipment.

49. The method of claim 48, wherein:
the first characteristics include, for each substrate of the first plurality of substrates, a first profile angle of a recess etched into the respective substrate proximate a respective center of the respective substrate; and
the second characteristics include, for each substrate of the first plurality of substrates, a second profile angle of a recess etched into the respective substrate proximate a respective edge of the respective substrate.

50. The method of claim 48, wherein:
the first characteristics include, for each substrate of the first plurality of substrates, a first depth of a recess etched into the respective substrate proximate a respective center of the respective substrate; and
the second characteristics include, for each substrate of the first plurality of substrates, a second depth of a recess etched into the respective substrate proximate a respective edge of the respective substrate.

51. The method of claim 48, wherein:
the first characteristics include, for each substrate of the first plurality of substrates, a first thickness of a film deposited on the respective substrate proximate a respective center of the respective substrate; and
the second characteristics include, for each substrate of the first plurality of substrates, a second thickness of the film proximate a respective edge of the respective substrate.

52. The method of claim 48, wherein:
performing the plasma semiconductor process having first process conditions on the first plurality of substrates further has third process conditions;
the third process conditions correspond to a first amplitude and a first phase of a signal applied to an electrode of the focus ring during the plasma semiconductor process;
determining the second process conditions further includes determining fourth process conditions to be applied while performing the plasma semiconductor process on the second plurality of substrates based on the first characteristics and the second characteristics;
the fourth process conditions correspond to a second amplitude and a second phase of a signal applied to the electrode of the focus ring during the plasma semiconductor process; and
performing the plasma semiconductor process having the second process conditions on the second plurality of substrates further has the fourth process conditions.
